(19) United States
(12) Patent Application Publication
(10) Pub. No.: US 2011/0057897 A1
(43) Pub. Date: Mar. 10, 2011

(54) TOUCH PANEL AND TOUCH SENSING DISPLAY

(76) Inventors: Wen-Chun WANG, Taichung City (TW); Chih-Jung Teng, Taichung City (TW); Kuo-Chang Su, Tai Nan County (TW)

(21) Appl. No.: 12/875,605

(22) Filed: Sep. 3, 2010

(30) Foreign Application Priority Data
Sep. 8, 2009 (TW) 098130306

(51) Int. Cl. G06F 3/041; H03K 17/975

(52) U.S. Cl. 345/173; 200/600

(57) ABSTRACT

A touch panel includes a cover glass, a first base plate and a second electrode layer. A first electrode layer is formed on a surface of the cover glass, and the first base plate is disposed on one side of the first electrode layer opposite the cover glass. The second electrode layer is formed on a surface of the first base plate opposite the first electrode layer.

### BACKGROUND OF THE INVENTION

a. Field of the Invention

The invention relates to a touch panel and a touch sensing display having the touch panel.

b. Description of the Related Art

Referring to FIG. 4, a conventional touch panel has two base plates 90, and an electrode layer 91 is formed on each of two surfaces facing each other and respectively on the two base plates 90. An insulation adhesive 92 is interposed between two electrode layers 91 to insulate the two electrode layers 91 from each other. A cover layer 93 is formed on a surface of the top base plate 90. However, the thickness of the insulating adhesive 92 interposed between two electrode layers 91 is difficult to maintain a fixed value during assembly, and this may considerably influence the accuracy of touch-sensing controls.

### BRIEF SUMMARY OF THE INVENTION

The invention provides a touch panel and a touch sensing display having fine assembly accuracy and simplified fabrication processes.

Other objects and advantages of the present invention may be further illustrated by the technical features broadly embodied and described as follows.

In order to achieve one or a portion of or all of the objects or other objects, one embodiment of the present invention provides a touch panel including a cover glass, a first base plate and a second electrode layer. A first electrode layer is formed on a surface of the cover glass, and the first base plate is disposed on one side of the first electrode layer opposite the cover glass. The second electrode layer is formed on a surface of the first base plate opposite the first electrode layer.

According to another embodiment of the invention, a touch-sensing display includes a cover glass, a color filter substrate, a second electrode layer, an insulation layer, a common electrode layer, a second base plate, and a liquid crystal layer. A first electrode layer is formed on a surface of the cover glass, and the color filter substrate is disposed on one side of the first electrode layer opposite the cover glass. The second electrode layer is formed on a surface of the color filter substrate opposite the first electrode layer. The insulation layer is formed on a surface of the second electrode layer opposite the color filter substrate. The common electrode layer is formed on a surface of the insulation layer opposite the second electrode layer. The second base plate is disposed parallel with the color filter substrate, and the liquid crystal layer is interposed between the common electrode layer and the second base plate.

The embodiment or the embodiments of the invention may have at least one of the following advantages. Since a first base plate serves as a dielectric layer of a touch panel to insulate two electrodes layers from each other, the thickness between two electrode layers is easy to maintain a fixed value during assembly to achieve high accuracy of capacitance touch-sensing controls.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 shows a schematic diagram of a touch panel according to an embodiment of the invention.

FIG. 2 shows a schematic diagram of a touch panel according to another embodiment of the invention.

FIG. 3 shows a schematic diagram of a touch-sensing display according to an embodiment of the invention.

FIG. 4 shows a schematic diagram of a conventional touch panel.

### DETAILED DESCRIPTION OF THE INVENTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

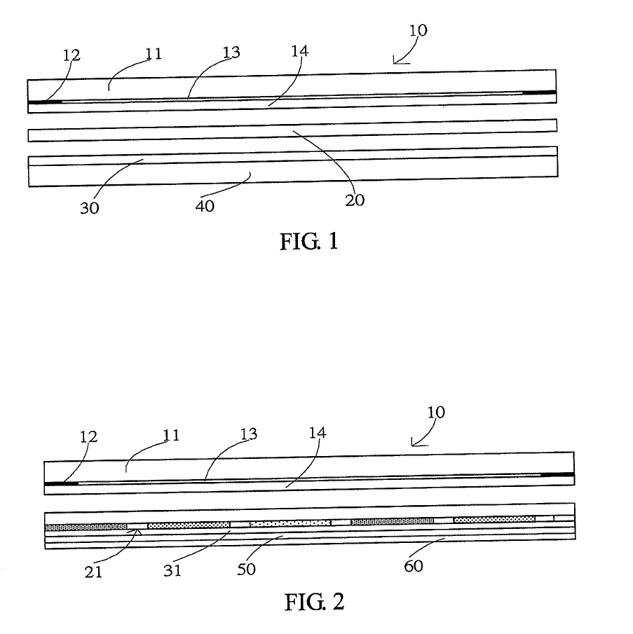

Referring to FIG. 1, a touch panel includes a cover glass 10 having a main body 11 and a decorative layer 12 formed on the periphery of a first surface of the main body 11. A flattened layer 13 is formed on the first surface of the main body 11 and surrounded by the decorative layer 12. The decorative layer 12 can be a ceramic layer, a diamond-like carbon layer or a printing ink layer with various colors, and has some decorative design such as patterns or characters. A first electrode layer 14 is formed on the flattened layer 13 and the decorative layer 12.

A first base plate 20 is disposed on one side of the first electrode layer 14 opposite the side where the flattened layer 13 and the decorative layer 12 is formed. The first base plate 20 may be a glass plate, a plastic plate, a hard plate, a soft plate, or a polarizer.

A second electrode layer 30 is disposed on one side of the first base plate 20 opposite the side where the first electrode layer 14 is formed.

A second base plate 40 is disposed parallel with the first base plate 20, and the second electrode layer 30 is formed on the second base plate 40. The second base plate 40 may be a glass plate, a plastic plate, a hard plate, a soft plate, or a color filter substrate. These structures are stacked to form a touch panel.

As shown in FIG. 2, the cover glass 10 has a first electrode layer 14 and the first base plate is a color filter substrate 21 wherein the second electrode layer 31 is formed on a surface of the color filter substrate 21 opposite the surface where the first electrode layer 14 is formed, and an insulation layer 50 and a common electrode layer 60 are formed in succession on a surface of the second electrode layer 31 opposite the surface where the color filter substrate 21 is formed. The cover glass 10 has a first electrode layerl4 that corresponds to the second electrode layer 31, and the insulation layer 50 between the first electrode layer 14 and the second electrode layer 31 is formed to correspond to the color filter substrate 21. These structures are stacked to form a touch panel.

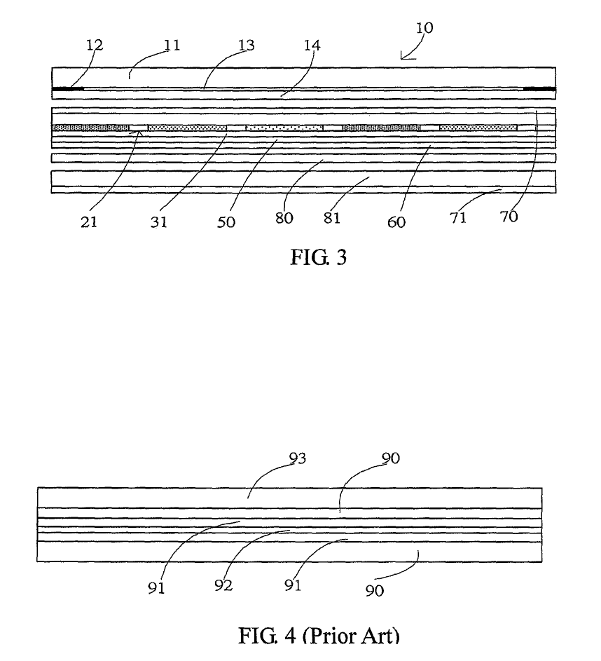

FIG. 3 shows a touch-sensing display incorporates a touch panel shown in FIG. 2. Referring to the touch-sensing display shown in FIG. 3, the color filter substrate 21 serves as a first base plate, and a top polarizer 70 is formed on a surface of the color filter substrate 21 and faces the first electrode layer 14 of the cover glass 10. The second electrode layer 31, the insulation layer 50 and the common electrode layer 60 are formed in succession on a surface of the color filter substrate 21 opposite the first electrode layer 14. Further, a liquid crystal layer 80 is interposed between the common electrode layer 60 and the second base plate 81 wherein the second base plate 81 may be an array substrate. A bottom polarizer 71 is formed on a surface of the second base plate 81 opposite the liquid crystal layer 80. Since the first base plate is a color filter substrate 21, a touch panel and a liquid crystal display are allowed to be integrated to form a touch-sensing display that has a simplified configuration.

The embodiment or the embodiments of the invention may have at least one of the following advantages. Since a first base plate serves as a dielectric layer of a touch panel to insulate two electrodes layers from each other, the thickness between two electrode layers is easy to maintain a fixed value during assembly to achieve high accuracy of capacitance touch-sensing controls. Moreover, the display integrated with the touch panel shown in FIG. 1 can be organic electroluminescence display, electrowetting display or bi-stable display.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A touch panel, comprising:
a cover glass, wherein a first electrode layer is formed on a surface of the cover glass;
a first base plate disposed on one side of the first electrode layer opposite the cover glass; and
a second electrode layer formed on a surface of the first base plate opposite the first electrode layer.

2. The touch panel as claimed in claim 1, wherein a second base plate is disposed on one side of the second electrode layer opposite the first base plate, and the second electrode layer is formed on the second base plate.

3. The touch panel as claimed in claim 1, wherein the second electrode layer is formed on the first base plate.

4. The touch panel as claimed in claim 1, wherein the cover glass has a main body, and a decorative layer is formed on the periphery of a surface of the main body facing the first electrode layer.

5. The touch panel as claimed in claim 4, further comprising:
a flattened layer formed on the surface of the main body and surrounded by the decorative layer.

6. The touch panel as claimed in claim 4, wherein the decorative layer is made with various colors.

7. The touch panel as claimed in claim 4, wherein patterns or characters are formed on the decorative layer.

8. The touch panel as claimed in claim 1, wherein the first base plate is a glass plate, a plastic plate, a hard plate, a soft plate, or a polarizer.

9. The touch panel as claimed in claim 2, wherein the second base plate is a glass plate, a plastic plate, a hard plate, or a soft plate.

10. The touch panel as claimed in claim 3, wherein the first base plate is a color filter substrate.

11. The touch panel as claimed in claim 10, further comprising:
an insulation layer and a common electrode layer formed in succession on a surface of the second electrode layer opposite the color filter substrate.

12. A touch-sensing display, comprising:
a cover glass, wherein a first electrode layer is formed on a surface of the cover glass;
a color filter substrate disposed on one side of the first electrode layer opposite the cover glass;
a second electrode layer formed on a surface of the color filter substrate opposite the first electrode layer;
an insulation layer formed on a surface of the second electrode layer opposite the color filter substrate;
a common electrode layer formed on a surface of the insulation layer opposite the second electrode layer;
a second base plate disposed parallel with the color filter substrate; and
a liquid crystal layer interposed between the common electrode layer and the second base plate.

13. The touch-sensing display as claimed in claim 12, further comprising:
a top polarizer formed on a surface of the color filter substrate and facing the cover glass; and
a bottom polarizer formed on a surface of the second base plate opposite the liquid crystal layer.

14. The touch-sensing display as claimed in claim 12, wherein the second substrate is an array substrate.

15. The touch-sensing display as claimed in claim 12, wherein the cover glass has a main body, and a decorative layer is formed on the periphery of a surface of the main body facing the first electrode layer.

16. The touch-sensing display as claimed in claim 15, further comprising:
a flattened layer formed on the surface of the main body and surrounded by the decorative layer.

17. The touch-sensing display as claimed in claim 15, wherein the decorative layer is made with various colors.

18. The touch-sensing display as claimed in claim 15, wherein the decorative layer is a ceramic layer, a diamond-like carbon layer or a printing ink layer.

19. The touch-sensing display as claimed in claim 15, wherein patterns or characters are formed on the decorative layer.

20. The touch-sensing display as claimed in claim 12, wherein the display is a organic electroluminescence display, a electrowetting display or a bi-stable display.
